(19) United States
(12) Patent Application Publication
(10) Pub. No.: US 2009/0168827 A1
(43) Pub. Date: Jul. 2, 2009

(54) Nitride semiconductor laser chip and method of fabricating same

(75) Inventors: Toshiyuki Kawakami, Mihara-shi (JP); Takeshi Kamikawa, Tenri-shi (JP); Kentaro Tani, Higashihiroshima-shi (JP)

Correspondence Address: HARNESS, DICKEY & PIERCE, P.L.C., P.O. BOX 8910, RESTON, VA, 20195, US

(73) Assignee: SHARP KABUSHIKI KAISHA

(21) Appl. No.: 12/318,237

(22) Filed: Dec. 23, 2008

(30) Foreign Application Priority Data
Dec. 26, 2007 (JP) 2007-333707

(51) Int. Cl. H01S 5/00; H01L 21/02

(52) U.S. Cl. 372/50.11; 438/29; 257/E21.002

(57) ABSTRACT

A nitride semiconductor laser chip is provided that can not only improve its COD level but also prevent its I-L characteristic curve from rising steeply and that can reduce an operating voltage. The nitride semiconductor laser chip includes layers constituting a nitride semiconductor layer and formed on an n-type GaN substrate, mirror facets including a light emission mirror facet and a light reflection mirror facet, a p-side ohmic contact formed on an upper contact layer to reach the mirror facets and a p-side pad contact formed in a region only a distance L1 away from the light emission mirror facet. The thickness d of the p-side ohmic contact and the distance L1 from the p-side ohmic contact to the light emission mirror facet are adjusted such that the amount of current injected into the light emission mirror facet is 20% or more but 70% or less of the amount of current injected into an area directly below the p-side pad contact.

This nonprovisional application claims priority under 35 U.S.C. §119(a) on Patent Application No. 2007-333707 filed in Japan on Dec. 26, 2007, the entire contents of which are hereby incorporated by reference.

### BACKGROUND OF THE INVENTION

1. Field of the Invention

The present invention relates to a nitride semiconductor laser chip and a method of fabricating such a nitride semiconductor laser chip.

2. Description of Related Art

It has been expected that nitride semiconductors, compounds of Al, Ga, In or the like of group III elements and N of group V elements would serve as semiconductor materials for light emitting devices and power devices due to their band structures and chemical stability, and various attempts have been made to use the nitride semiconductors in a variety of applications. Today, in nitride semiconductor laser chips for one of these applications, namely, for use as light sources for optical information recording devices such as an optical disc drive, since GaN substrates are employed, crystal growth technology is enhanced, superior methods for designing chip structures are employed, wafer process technology is enhanced and other advancements are made, high reliability and cost reduction are achieved. Thus, markets are emerging.

The next development target for such optical information recording devices is to double writing speed and apply them to devices such as mobile devices. Thus, in the nitride semiconductor laser chips for use as light sources for optical information recording devices, a higher power output, a further enhancement in reliability, cost reduction, lower power consumption and the like are increasingly required. It is known that in order to meet the requirement of producing a higher power output, among others, it is possible to enhance the light output level of the nitride semiconductor laser chip by preventing COD (catastrophic optical damage) from occurring near a mirror facet of the nitride semiconductor laser chip where light is emitted and the chip is most likely to be damaged. Such a nitride semiconductor laser chip is disclosed in, for example, JP-A-2003-031894.

FIG. 24 is a perspective view showing, in a simplified manner, a conventional nitride semiconductor laser chip disclosed in JP-A-2003-031894. As shown in FIG. 24, in the conventional nitride semiconductor laser chip 100 disclosed in JP-A-2003-031894, a multilayer structure 102 of a nitride semiconductor required for lasing is formed on a substrate 101. In this multilayer structure 102, a ridge stripe 103 serving as a current path is formed, and buried layers 104 are formed on both sides of the ridge stripe 103. An ohmic contact 105 is formed on the upper surfaces of the ridge stripe 103 and the buried layers 104. This ohmic contact 105 is formed in a region a predetermined distance away from the mirror facet 110 of a resonator. Thus, current is prevented from being injected into the region between the ohmic contact 105 and the mirror facet 110. Specifically, a current injection prevention region 120 into which current is prevented from being injected is formed near the mirror facet 110.

In the conventional nitride semiconductor laser chip 100 configured as described above, the current injection prevention region 120 is provided in the vicinity of the mirror facet 110. Thus, it is possible to prevent COD near the mirror facet 110. This makes it possible to improve its COD level, and thus its light output level can be increased.

However, when the inventors of the present invention fabricated the same nitride semiconductor laser chips as the conventional nitride semiconductor laser chip 100 shown in FIG. 24 and measured their injection current-light output characteristic (I-L characteristic), they found that a large number of chips showed a steeply rising curve as shown in FIG. 25. Disadvantageously, when the nitride semiconductor laser chip showing such a steeply rising curve is used as a light source for an optical information recording device, it becomes very difficult to stably read information from an optical disc medium. When the information is read from the optical disc medium, the laser output of the nitride semiconductor laser chip is lowered. Thus, output light in an output region near the rising portion of the I-L characteristic curve is used. Hence, when the I-L characteristic curve rises steeply, it becomes difficult to, for example, adjust light output. This makes it difficult to stably read information.

Probably, the I-L characteristic curve steeply rises for the following reason. When the current injection prevention region is formed near the mirror facet of the resonator, a region near the mirror facet is more likely to become a saturable absorption region where light is absorbed. When the saturable absorption region exists near the mirror facet, the saturable absorption region absorbs light and thus becomes transparent to laser light at the saturation stage. Thus, lasing is caused abruptly. This probably causes an I-L characteristic curve to rise steeply.

As described above, although the conventional nitride semiconductor laser chip 100 can improve its COD level, it disadvantageously shows a steeply rising I-L characteristic curve. Even if the conventional nitride semiconductor laser chip 100 that not only improves its COD level but also shows a stably rising I-L characteristic curve can be obtained, it is very difficult to produce it with a high yield. Furthermore, the provision of the current injection prevention region 120 in the vicinity of the mirror facet 110 disadvantageously reduces the region into which current is injected, with the result that a voltage is increased and this increases an operating voltage.

### SUMMARY OF THE INVENTION

The present invention is intended to overcome the above-described disadvantages. An object of the invention is to provide a nitride semiconductor laser chip that can not only improve its COD level but also prevent its I-L characteristic curve from rising steeply and that can reduce an operating voltage.

Another object of the invention is to provide a method of fabricating, with a high yield, a nitride semiconductor laser chip that can not only improve its COD level but also prevent its I-L characteristic curve from rising steeply and that can reduce an operating voltage.

To achieve the above objects, the inventors of the present invention carefully studied and found that, by injecting current also into the vicinity of a mirror facet (a light emission mirror facet) and adjusting such an amount of injected current to a predetermined amount, it is possible to allow the I-L characteristic curve to rise stably without degrading the COD level.

Thus, according to a first aspect of the present invention, there is provided a nitride semiconductor laser chip including: a nitride semiconductor layer formed on a substrate; a pair of mirror facets that is formed on the nitride semiconductor layer and that includes a light emission mirror facet; a first metal contact layer formed on the nitride semiconductor layer; and a second metal contact layer formed, in a predetermined region on the nitride semiconductor layer and at a predetermined distance away from the light emission mirror facet, such that the second metal contact layer covers part of the first metal contact layer. The nitride semiconductor laser chip is configured such that the amount of current injected into the light emission mirror facet is 20% or more but 70% or less of the amount of current injected into an area directly below the second metal contact layer.

In the nitride semiconductor laser chip according to the first aspect of the invention, as described above, by setting the amount of current injected into the light emission mirror facet at 20% or more of the amount of current injected into the area directly below the second metal contact layer, it is possible to prevent the I-L characteristic curve from disadvantageously rising steeply due to the fact that the amount of current injected into the light emission mirror facet is less than 20% of the amount of current injected into the area directly below the second metal contact layer. That is, even if 20% or more of the amount of current injected into the area directly below the second metal contact layer is injected into the light emission mirror facet and thus the saturable absorption region exists in the vicinity of the mirror facet, it is possible to reduce the light loss occurring in the saturable absorption region in the vicinity of the mirror facet. This makes it possible to effectively reduce the amount of light absorbed. Thus, it is possible to prevent the rapid occurrence of lasing. This helps prevent the I-L characteristic curve from rising steeply.

In the nitride semiconductor laser chip according to the first aspect of the invention, as described above, by setting the amount of current injected into the light emission mirror facet at 70% or less of the amount of current injected into the area directly below the second metal contact layer, it is possible to avoid the disadvantage of making it difficult to improve the COD level due to the fact that the amount of current injected into the light emission mirror facet is more than 70% of the amount of current injected into the area directly below the second metal contact layer. As described above, in the nitride semiconductor laser chip according to the first aspect of the invention, by setting the amount of current injected into the light emission mirror facet at 20% or more but 70% or less of the amount of current injected into the area directly below the second metal contact layer, it is possible not only to improve its COD level but also to prevent its I-L characteristic curve from rising steeply.

With this configuration, since a predetermined amount of current is also injected into the vicinity of the light emission mirror facet, it is possible to reduce the operating voltage as compared with a conventional nitride semiconductor laser chip having a current injection prevention region in which no current is injected into the vicinity of the light emission mirror facet (the mirror facet).

Preferably, in the nitride semiconductor laser chip according to the first aspect of the invention, the first metal contact layer is formed to have a thickness d and reach the light emission mirror facet, the second metal contact layer is formed in a region only a distance L1 away from the light emission mirror facet and the thickness d of the first metal contact layer and the distance L1 from the second metal contact layer to the light emission mirror facet are adjusted such that the amount of current injected into the light emission mirror facet is 20% or more but 70% or less of the amount of current injected into the area directly below the second metal contact layer. With this configuration, it is possible to easily adjust the amount of current injected into the light emission mirror facet and thus easily adjust the amount of current injected into the light emission mirror facet to 20% or more but 70% or less of the amount of current injected into the area directly below the second metal contact layer. This makes it easily possible not only to improve its COD level but also to prevent its I-L characteristic curve from rising steeply.

With this configuration, since both the distance L1 from the second metal contact layer to the light emission mirror facet and the thickness d of the first metal contact layer are varied and this allows the amount of current injected into the light emission mirror facet to be adjusted, it is possible to keep the distance L1 from the second metal contact layer to the light emission mirror facet equal to or more than a predetermined distance. Thus, it is possible to prevent the distance L1 from the second metal contact layer to the light emission mirror facet from being unduly reduced. Hence, it is possible to avoid the disadvantage of, for example, making it difficult to divide (separate) the chips due to the fact that the distance L1 is unduly reduced. This makes it possible to facilitate the fabrication process. This helps obtain, with a high yield, the nitride semiconductor laser chip that can not only improve its COD level but also prevent its I-L characteristic curve from rising steeply.

According to a second aspect of the present invention, there is provided a nitride semiconductor laser chip including: a nitride semiconductor layer formed on a substrate; a pair of mirror facets that is formed on the nitride semiconductor layer and that includes a light emission mirror facet; a first metal contact layer formed on the nitride semiconductor layer; and a second metal contact layer formed, in a predetermined region on the nitride semiconductor layer and at a predetermined distance away from the light emission mirror facet, such that the second metal contact layer covers part of the first metal contact layer. The nitride semiconductor laser chip is configured such that the first metal contact layer is formed to have a thickness d and reach the light emission mirror facet, the second metal contact layer is formed in a region only a distance L1 away from the light emission mirror facet and a relationship between the thickness d of the first metal contact layer and the distance L1 from the second metal contact layer to the light emission mirror facet is given by formula below:

$$161 \leq \frac{L 1}{\sqrt{d}} \leq 727.$$

In the nitride semiconductor laser chip according to the second aspect of the invention, as described above, by forming the first metal contact layer having the thickness d such that it reaches the light emission mirror facet and forming the second metal contact layer in the region only the distance L1 away from the light emission mirror facet, it is possible to inject current also into the vicinity of the light emission mirror facet. Moreover, by setting the thickness d and the distance L1 such that the relationship between the thickness d of the first metal contact layer and the distance L1 from the second metal contact layer to the light emission mirror facet satisfies the above formula, it is possible to inject into the light emission mirror facet a predetermined amount of current smaller than the amount of current injected into the area directly below the second metal contact layer. Thus, it is possible not only to improve its COD level but also to prevent its I-L characteristic curve from rising steeply.

With this configuration, since the predetermined amount of current is also injected into the vicinity of the light emission mirror facet, it is possible to reduce the operating voltage as compared with the conventional nitride semiconductor laser chip having a current injection prevention region in which no current is injected into the vicinity of the light emission mirror facet (the mirror facet).

Preferably, in the nitride semiconductor laser chips according to the first and second aspects of the invention, the nitride semiconductor layer includes an n-type semiconductor layer, an active layer and a p-type semiconductor layer formed one after another on the substrate from the substrate and further includes a current path that is formed on at least one of layers constituting the nitride semiconductor layer and that extends perpendicular to the mirror facets, the first metal contact layer is so formed on the current path as to come into contact with the p-type semiconductor layer and the second metal contact layer is so formed on the p-type semiconductor layer as to come into contact with part of the first metal contact layer. With this configuration, it is easily possible not only to improve its COD level but also to prevent its I-L characteristic curve from rising steeply and to reduce the operating voltage.

The thickness d of the first metal contact layer is preferably 0.005 μm or more but 0.1 μm or less. With this configuration, it is possible to avoid the disadvantage of making it difficult, due to the fact that the thickness d of the first metal contact layer is smaller than 0.005 μm, to stably form the first metal contact layer as a layer (film) without undergoing three-dimensional growth when the first metal contact is formed. Here, the three-dimensional growth means that, in the early stages of formation of a thin film, an action in which energy is decreased by reducing a surface area is exerted and this produces not a film but an island with a seed for film growth in its center. In such a film formed by three-dimensional growth, it is difficult to achieve electrical conduction. Moreover, by setting the thickness d of the first metal contact layer at 0.005 μm or more, it is possible to prevent the first metal contact layer from being degraded due to increased temperature resulting from, for example, heat generated by the chip when the chip is driven. By setting the thickness d of the first metal contact layer at 0.005 μm or more in this way, it is possible to obtain the first metal contact layer suitable for the injection of current into the vicinity of the light emission mirror facet. By setting the thickness d of the first metal contact layer at 0.1 μm or less, it is possible to prevent the resistance of the first metal contact layer from being disadvantageously and unduly reduced due to the fact that the thickness d of the first metal contact layer is larger than 0.1 μm. Thus, it is possible to reduce the amount of current injected into the vicinity of the light emission mirror facet without causing adverse effects on the other characteristics of the chip. This makes it possible to improve the COD level.

In this case, the thickness d of the first metal contact layer is preferably 0.01 μm or more but 0.5 μm or less. With this configuration, it is easily possible not only to obtain the first metal contact layer suitable for the injection of current into the vicinity of the light emission mirror facet but also to reduce the amount of current injected into the vicinity of the light emission mirror facet without causing adverse effects on the other characteristics of the chip.

In this case, the thickness d of the first metal contact layer is more preferably 0.01 μm or more but 0.025 μm or less. With this configuration, it is possible to prevent variations in the quality of the etching of the first metal contact layer when the etching is performed on the first metal contact layer. This makes it possible to prevent the first metal contact layer from being poorly formed. With this configuration, it is also possible to prevent adherence of the first metal contact layer and thus facilitate the fabrication of the nitride semiconductor laser chip. Consequently, production yields can be improved. With this configuration, it is also easily possible not only to obtain the first metal contact layer suitable for the injection of current into the vicinity of the light emission mirror facet but also to reduce the amount of current injected into the vicinity of the light emission mirror facet without causing adverse effects on the other characteristics of the chip.

Preferably, in the nitride semiconductor laser chips according to the first and second aspects of the invention, the thickness of the second metal contact layer is larger than that of the first metal contact layer. With this configuration, it is possible to reduce the resistance of the second metal contact layer. This makes it possible to make substantially constant the amount of current injected into the area directly below the second metal contact layer. Thus, it is possible to make substantially constant the amount of current injected from the second metal contact layer to the first metal contact layer without producing voltage drops.

In the configuration in which the second metal contact layer is formed in the region only the distance L1 away from the light emission mirror facet, the distance L1 from the second metal contact layer to the light emission mirror facet is preferably 20% or less of a distance between the mirror facets (a laser length). With this configuration, it is possible to prevent the amount of current injected into the entire chip from being unduly reduced due to the fact that the distance L1 from the second metal contact layer to the light emission mirror facet is more than 20% of the distance between the mirror facets (the laser length). Thus, it is possible to prevent the operating, voltage (drive voltage) from being increased.

Preferably, in the configuration where the second metal contact layer is formed in the region only the distance L1 away from the light emission mirror facet, the pair of mirror facets includes a light reflection mirror facet opposite the light emission mirror facet and a distance from the light reflection mirror facet to the second metal contact layer is smaller than the distance L1 from the light emission mirror facet to the second metal contact layer. With this configuration, it is possible to easily prevent the amount of current injected into the entire chip from being reduced. Thus, it is possible to easily prevent the operating voltage (drive voltage) from being increased.

In the nitride semiconductor laser chips according to the first and second aspects of the invention, the pair of mirror facets can each be formed by cleavage.

According to a third aspect of the present invention, there is provided a method of fabricating a nitride semiconductor laser chip, the method including the steps of: growing an n-type semiconductor layer, an active layer and a p-type semiconductor layer one after another on a substrate, the layers being a nitride semiconductor layer; forming, on at least one of layers constituting the nitride semiconductor layer, a current path extending in a predetermined direction; forming, on the current path, a first metal contact layer coming into contact with the p-type semiconductor layer; forming a second metal contact layer on the p-type semiconductor layer so as to cover part of the first metal contact layer; and forming a mirror facet by cleaving the substrate in a direction perpendicular to a direction in which the current path extends. Here, the step of forming the second metal contact layer includes a step of forming a plurality of second metal contact layers spaced a predetermined distance apart in the direction in which the current path extends and the step of forming the mirror facet includes a step of cleaving the substrate such that, as seen in a plan view, a distance from a position where the mirror facet is formed to one of the adjacent second metal contact layers is different from a distance from the position where the mirror facet is formed to the other adjacent second metal contact layer.

With the method of fabricating a nitride semiconductor laser chip according to the third aspect of the invention, as described above, by forming a plurality of second metal contact layers spaced a predetermined distance apart in the direction in which the current path extends and cleaving the substrate such that a distance from a position where the mirror facet is formed to one of the adjacent second metal contact layers is different from a distance from the position where the mirror facet is formed to the other adjacent second metal contact layer, it is possible to simultaneously form the light emission mirror facet of one of the adjacent chips (laser chips) and the light reflection mirror facet of the other adjacent chip (laser chip) and to easily adjust the distance from the light reflection mirror facet to the one of the adjacent second metal contact layers such that it is larger than the distance form the light reflection mirror facet to the other adjacent second metal contact layer. Thus, it is possible to easily adjust the amount of current injected into the light emission mirror facet to a predetermined amount (20% or more but 70% or less) that is smaller than the amount of current injected into the area directly below the second metal contact layer. This makes it possible to easily fabricate the nitride semiconductor laser chip that can not only improve its COD level but also prevent its I-L characteristic curve from rising steeply. Consequently, the nitride semiconductor laser chip can be fabricated with a high yield.

By adjusting the distance from one of the adjacent second metal contact layers to the other adjacent second metal contact layer in the direction in which the current path extends to a predetermined distance that makes it easy to perform cleavage, it is possible to easily separate the chips. With the method of fabricating a nitride semiconductor laser chip according to the third aspect of the invention, the distance from the light reflection mirror facet to the second metal contact layer can be easily set smaller than that from the light emission mirror facet to the second metal contact layer. Thus, it is possible to easily fabricate the nitride semiconductor laser chip in which the operating voltage (drive voltage) is prevented from being increased (in which the operating voltage can be reduced).

As described above, according to the present invention, it is possible to easily obtain a nitride semiconductor laser chip that can not only improve its COD level but also prevent its I-L characteristic curve from rising steeply and that can reduce an operating voltage.

With the fabrication method according to the invention, it is possible to fabricate, with a high yield, a nitride semiconductor laser chip that can not only improve its COD level but also prevent its I-L characteristic curve from rising steeply and that can reduce an operating voltage.

### BRIEF DESCRIPTION OF THE DRAWINGS

FIG. 1 is an overall perspective view of a nitride semiconductor laser chip according to an embodiment of the present invention;

FIG. 2 is a plan view of the nitride semiconductor laser chip according to the embodiment of the invention;

FIG. 3 is a cross-sectional view of the nitride semiconductor laser chip according to the embodiment of the invention;

FIG. 4 is a cross-sectional view taken along line 80-80 of FIG. 2;

FIG. 5 is an enlarged cross-sectional view showing part of the active layer of the nitride semiconductor laser chip according to the embodiment of the invention;

FIG. 6 is a schematic diagram showing the amount of injected current in the nitride semiconductor laser chip according to the embodiment of the invention;

FIG. 7 is a graph showing the relationship between a distance from a p-side pad contact to a light emission mirror facet and a current injection ratio;

FIG. 8 is a graph showing the measurement results of the characteristics of the chip;

FIG. 9 is a diagram showing an example of the I-L characteristic curve of the nitride semiconductor laser chip according to the embodiment of the invention;

FIG. 10 is a cross-sectional view for describing a method of fabricating the nitride semiconductor laser chip according to the embodiment of the invention;

FIG. 11 is another cross-sectional view for describing the method of fabricating the nitride semiconductor laser chip according to the embodiment of the invention;

FIG. 12 is another cross-sectional view for describing the method of fabricating the nitride semiconductor laser chip according to the embodiment of the invention;

FIG. 13 is another cross-sectional view for describing the method of fabricating the nitride semiconductor laser chip according to the embodiment of the invention;

FIG. 14 is another cross-sectional view for describing the method of fabricating the nitride semiconductor laser chip according to the embodiment of the invention;

FIG. 15 is another cross-sectional view for describing the method of fabricating the nitride semiconductor laser chip according to the embodiment of the invention;

FIG. 16 is another cross-sectional view for describing the method of fabricating the nitride semiconductor laser chip according to the embodiment of the invention;

FIG. 17 is another cross-sectional view for describing the method of fabricating the nitride semiconductor laser chip according to the embodiment of the invention;

FIG. 18 is another cross-sectional view for describing the method of fabricating the nitride semiconductor laser chip according to the embodiment of the invention;

FIG. 19 is another cross-sectional view for describing the method of fabricating the nitride semiconductor laser chip according to the embodiment of the invention;

FIG. 20 is another cross-sectional view for describing the method of fabricating the nitride semiconductor laser chip according to the embodiment of the invention;

FIG. 21 is another cross-sectional view for describing the method of fabricating the nitride semiconductor laser chip according to the embodiment of the invention;

FIG. 22 is another cross-sectional view for describing the method of fabricating the nitride semiconductor laser chip according to the embodiment of the invention;

FIG. 23 is another cross-sectional view for describing the method of fabricating the nitride semiconductor laser chip according to the embodiment of the invention;

FIG. 24 is a perspective view showing, in a simplified manner, a conventional nitride semiconductor laser chip disclosed in JP-A-2003-031894; and

FIG. 25 is a diagram showing an example of the I-L characteristic curve of the conventional nitride semiconductor laser chip.

### DETAILED DESCRIPTION OF PREFERRED EMBODIMENTS

An embodiment according to the present invention will be described in detail below with reference to the accompanying drawings.

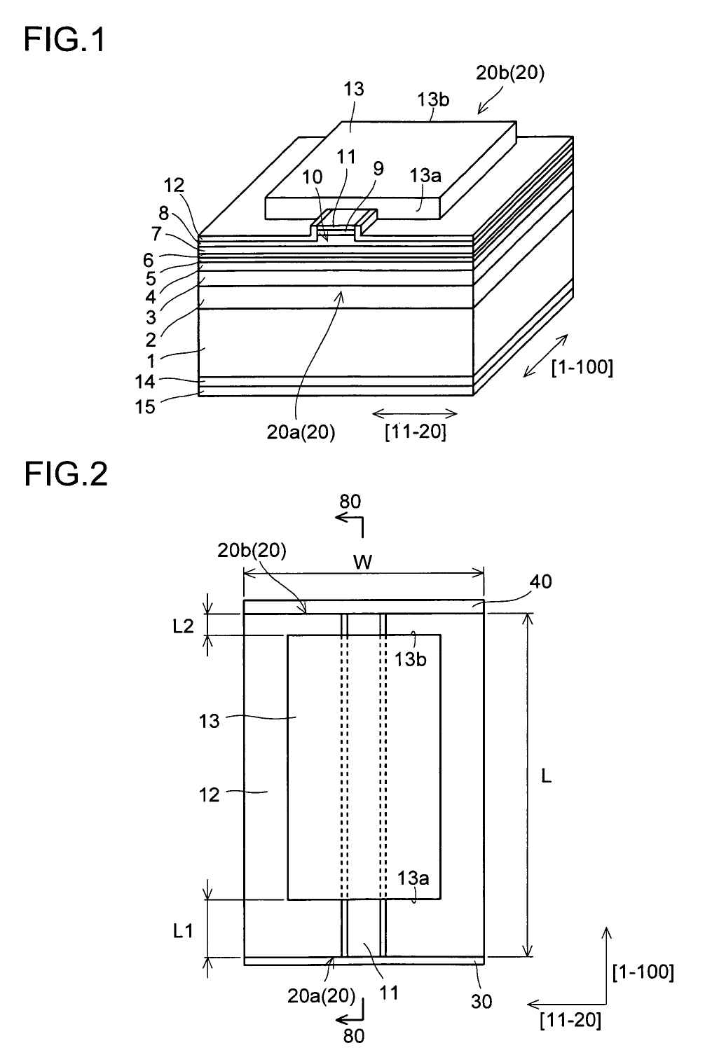

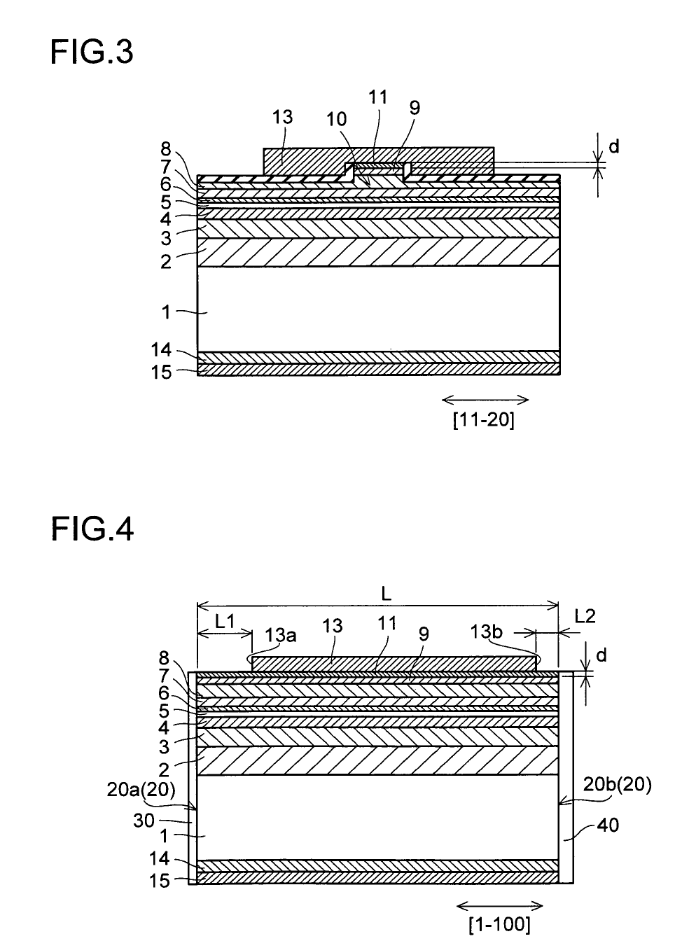

FIG. 1 is an overall perspective view of a nitride semiconductor laser chip according to the embodiment of the invention. FIG. 2 is a plan view of the nitride semiconductor laser chip according to the embodiment of the invention. FIG. 3 is a cross-sectional view of the nitride semiconductor laser chip according to the embodiment of the invention. FIGS. 4 to 6 are diagrams for describing the structure of the nitride semiconductor laser chip according to the embodiment of the invention. A description will now be given of the structure of the nitride semiconductor laser chip according to the embodiment of the invention with reference to FIGS. 1 to 6.

As shown in FIGS. 1 and 2, the nitride semiconductor laser chip of the embodiment is formed by cleavage and has a pair of opposite mirror facets 20 of a resonator (hereinafter, mirror facets 20). This pair of mirror facets 20 includes a light emission mirror facet 20a where laser light is emitted and a light reflection mirror facet 20b disposed on the opposite side of the light emission mirror facet 20a. The nitride semiconductor laser chip of the embodiment has a length L (a laser length L) of about 800 μm in a direction ([1-100] direction) perpendicular to the mirror facets 20 and a width W (a resonator width W) of about 400 μm in a direction ([11-20] direction) along the mirror facets 20.

As shown in FIGS. 1 and 3, in the nitride semiconductor laser chip of the embodiment, a lower contact layer 2 having a thickness of about 0.1 μm to about 10 μm (for example, about 4 μm) and formed of n-type GaN is formed on the (0001) face of an n-type GaN substrate 1. On the lower contact layer 2, a lower cladding layer 3 having a thickness of about 0.5 μm to about 3.0 μm (for example, about 2 μm) and formed of n-type Al_{0.05}Ga_{0.95}N is formed. On the lower cladding layer 3, a lower guiding layer 4 having a thickness of 0 to about 0.2 μm (for example, about 0.1 μm) and formed of n-type GaN is formed. On the lower guiding layer 4, an active layer 5 is formed.

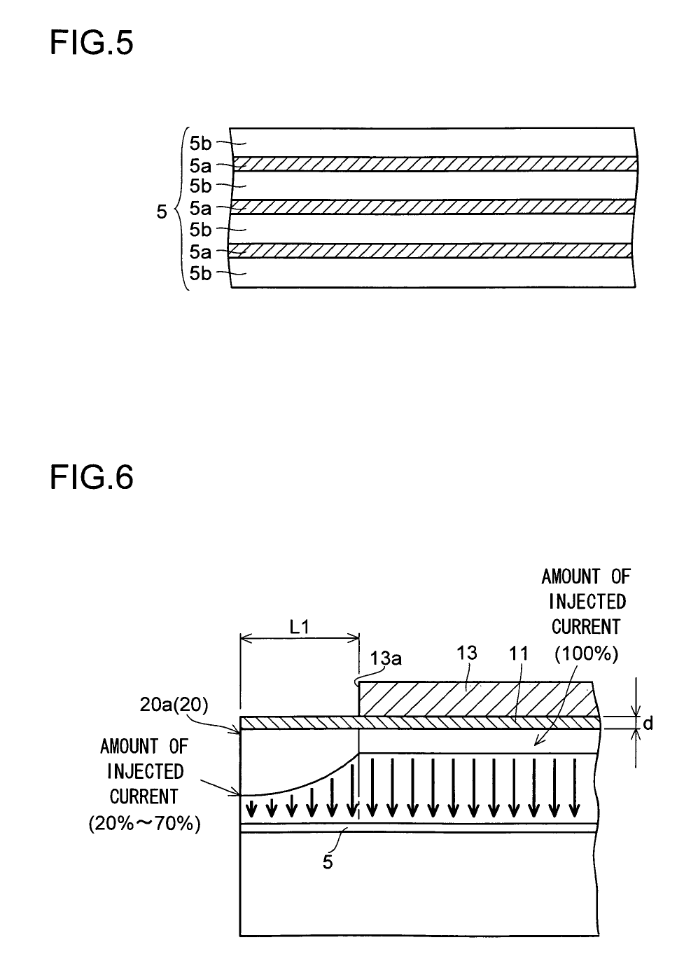

As shown in FIG. 5, the active layer 5 has a multiple quantum well (MQW) structure in which three quantum well layers 5a formed of Inₓ₁Ga₁₋ₓ₁N and four barrier layers 5b (where x1>x2) formed of Inₓ₂Ga₁₋ₓ₂N are alternately deposited. The quantum well layers 5a, for example, are each about 4 nm thick and are formed of Inₓ₁Ga₁₋ₓ₁N (x1=0.05 to 0.1). The barrier layers 5b, for example, are each about 8 nm thick and are formed of Inₓ₂Ga₁₋ₓ₂N (x2=0 to 0.05).

As shown in FIGS. 1 and 3, on the active layer 5, an evaporation prevention layer 6 having a thickness of 0 to about 0.02 μm (for example, about 0.01 μm) and formed of p-type Al_{0.3}Ga_{0.7}N is formed. On the evaporation prevention layer 6, an upper guiding layer 7 having a thickness of 0 to about 0.2 μm (for example, about 0.01 μm) and formed of p-type GaN is formed. On the upper guiding layer 7, an upper cladding layer 8 having a projection portion and flat portions other than the projection portion and formed of p-type Al_{0.05}Ga_{0.95}N is formed.

On the projection portion of the upper cladding layer 8, an upper contact layer 9 having a thickness of about 0.01 μm to about 1.0 μm (for example, about 0.05 μm) and formed of p-type GaN is formed. A stripe-shaped (elongated) ridge portion 10 having a width of about 1 μm to about 3 μm (for example, about 1.5 μm) is formed by the upper contact layer 9 and the projection portion of the upper cladding layer 8. As shown in FIG. 2, the ridge portion 10 is formed to extend in the direction ([1-100] direction) perpendicular to the mirror facets 20. The n-type GaN substrate 1 is an example of a “substrate” according to the present invention. The ridge portion 10 is an example of a “current path” according to the invention. Moreover, the lower contact layer 2, the lower cladding layer 3 and the lower guiding layer 4 are each an example of an “n-type semiconductor layer”; the evaporation prevention layer 6, the upper guiding layer 7, the upper cladding layer 8 and the upper contact layer 9 are each an example of a “p-type semiconductor layer”.

As shown in FIGS. 1 to 3, on the upper contact layer 9 of the ridge portion 10, a p-side ohmic contact 11 having a thickness d (see FIG. 3) is formed such that it is stripe-shaped (elongated). This p-side ohmic contact 11 is formed to come into direct contact with the upper contact layer 9. Disadvantageously, in nitride semiconductors, a p-type semiconductor has a high resistivity, and this makes it difficult to generate p-type charge carriers. Consequently, it is difficult to achieve ohmic contact. Thus, in order to make ohmic contact with the upper contact layer 9, the p-side ohmic contact 11 is formed of Pd (palladium), which is a metallic material having a large work function. The p-side ohmic contact 11 is formed such that one end and the other end thereof in its longitudinal direction ([1-100] direction) reach the light emission mirror facet 20a and the light reflection mirror facet 20b, respectively. That is, the p-side ohmic contact 11 is configured such that its longitudinal length is substantially equal to the laser length L. The p-side ohmic contact 11 is an example of a “first metal contact layer” according to the present invention.

In this embodiment, the thickness d of the p-side ohmic contact 11 is set at 5 nm (0.005 μm) or more but 100 nm (0.1 μm) or less (for example, about 15 nm).

On both sides of the ridge portion 10, buried layers 12 for confining current are formed. Specifically, on the upper cladding layer 8 and on the sides of the upper contact layer 9 and the p-side ohmic contact 11, the buried layers 12 that have a thickness of about 0.1 μm to about 0.3 μm (for example, about 0.15 μm) and have SiO₂ as the main ingredient are formed. With this configuration, it is possible to confine light in a horizontal traverse mode and a vertical transverse mode. When the thickness of the buried layers 12 is less than 50 nm, a waveguide loss may be caused by light absorption. Except when such a property (light absorption) is actively utilized, the thickness is preferably set at 50 nm or more.

On the upper surfaces of the buried layers 12, a p-side pad contact 13 having a larger surface area than that of the p-side ohmic contact 11 is formed so as to cover part of the p-side ohmic contact 11. As shown in FIGS. 2 to 4, in the area where the p-side pad contact 13 covers the part of the p-side ohmic contact 11, the p-side pad contact 13 comes into direct contact with the p-side ohmic contact 11. The p-side pad contact 13 has a multilayer structure where a Ti layer (unillustrated), a Mo layer (unillustrated) and an Au layer (unillustrated) are deposited one after another from the side of the buries layers 12. As shown in FIG. 3, the electrical resistance (film resistance) of the p-side pad contact 13 is lowered so that an electric current is supplied to the p-side ohmic contact 11 from the outside. Specifically, the p-side pad contact 13 is configured such that its thickness is larger than the thickness d of the p-side ohmic contact 11. More specifically, the total thickness of the p-side pad contact 13 is set at about 0.2 μm. Thus, it is possible to inject current into the p-side ohmic contact 11 in a substantially uniform manner without producing voltage drops.

In this embodiment, as shown in FIG. 2, the p-side pad contact 13 is formed such that it is substantially rectangular, as seen in a plan view. The p-side pad contact 13 is disposed in a region located at predetermined distances away from the mirror facets 20 (the light emission mirror facet 20a and the light reflection mirror facet 20b). Specifically, as shown in FIGS. 2 and 4, the p-side pad contact 13 is formed such that one mirror facet 13a (on the side of the light emission mirror facet 20a) of the p-side pad contact 13 is located at a position only a distance L1 (for example, about 25 μm) inward away from the light emission mirror facet 20a and the other mirror facet 13b (on the side of the light reflection mirror facet 20b) of the p-side pad contact 13 is located at a position only a distance L2 (for example, about 5 μm) inward away from the light reflection mirror facet 20b.

In this embodiment, the distance L2 from the light reflection mirror facet 20b to the p-side pad contact 13 is set shorter than the distance L1 from the light emission mirror facet 20a to the p-side pad contact 13. The distance L1 between the light emission mirror facet 20a and the p-side pad contact 13 is set at 20 percent or less of the laser length L (the distance between the light emission mirror facet 20a and the light reflection mirror facet 20b). The p-side pad contact 13 is an example of a “second metal contact layer” according to the present invention.

As shown in FIGS. 1, 3 and 4, on the back of the n-type GaN substrate 1, an n-side metal contact 14 is formed that has a multilayer structure where an Hf layer (unillustrated) and an Al layer (unillustrated) are deposited one after another from the back side of the n-type GaN substrate 1. On the n-side metal contact 14, an n-side pad contact 15 is formed that has a multilayer structure where a Mo layer (unillustrated), a Pt layer (unillustrated) and an Au layer (unillustrated) are deposited one after another from the side of the n-side metal contact 14. The n-side pad contact 15 is formed to facilitate the mounting of the nitride semiconductor laser chip on a submount (unillustrated).

As shown in FIGS. 2 and 4, on the light emission mirror facet 20a, there is formed an AR (anti-reflection) coating layer 30 composed of two layers in which an aluminum nitride layer (unillustrated) and an aluminum oxide layer (unillustrated), for example, are deposited from the side of the light emission mirror facet 20a. On the light reflection mirror facet 20b, there is formed a HR (high-reflection) coating layer 40 in which silicon oxide layers (unillustrated) and titanium oxide layers (unillustrated), for examples, are alternately deposited such that a total of nine layers are deposited.

In the nitride semiconductor laser chip configured as described above and according to the embodiment, the p-side pad contact 13 is formed in the region located only a predetermined distance L1 away from the light emission mirror facet 20a, and the p-side ohmic contact 11 is formed to reach the light emission mirror facet 20a (the mirror facet 20). Thus, a current is also injected, through the p-side ohmic contact 11, into the vicinity of the light emission mirror facet 20a (the region from the light emission mirror facet 20a to the p-side pad contact 13 (the region in the distance L1)).

The resistivity of the nitride semiconductor is relatively high, and, for example, the resistivity of the p-type GaN is about 1 Ω·cm. Thus, it cannot be expected that current extends on the order of micrometers within the nitride semiconductor. Hence, the amount of current injected into the vicinity of the light emission mirror facet 20a is controlled by the p-side ohmic contact 11, and the injected current can probably drive the active layer 5 without being affected. For this reason, as shown in FIG. 6, in the course of extension of current in a direction from the mirror facet 13a of the p-side pad contact 13 to the light emission mirror facet 20a, the amount of current injected into the vicinity of the light emission mirror facet 20a (the region from the p-side pad contact 13 to the light emission mirror facet 20a (the region in the distance L1)) is varied according to the amount of voltage drop caused by the resistance of the p-side ohmic contact 11.

Thus, it is possible to adjust the amount of current injected into the vicinity of the light emission mirror facet 20a by adjusting the thickness d of the p-side ohmic contact 11 and the distance L1 from the p-side pad contact 13 to the light emission mirror facet 20a. In the nitride semiconductor laser chip of the embodiment, the amount of current injected into the active layer 5 through the light emission mirror facet 20a is set at 20% or more but 70% or less of the amount of current injected into the active layer 5 through an area directly below the p-side pad contact 13 by adjusting the thickness d of the p-side ohmic contact 11 and the distance L1 from the p-side pad contact 13 to the light emission mirror facet 20a.

In this embodiment, the distance L1 (μm) from the light emission mirror facet 20a to the p-side pad contact 13 and the thickness d (μm) of the p-side ohmic contact 11 are set to satisfy formula (1) below.

$$161 \leq \frac{L 1}{\sqrt{d}} \leq 727 \qquad ( 1 )$$

Thus, it is possible not only to improve a COD level but also to prevent an I-L characteristic curve from rising steeply.

The reason for setting restrictions on the side of the light emission mirror facet 20a is as follows. The reflectivity of the light emission mirror facet 20a is lower than that of the light reflection mirror facet 20b due to the coatings formed on the mirror facets 20. Thus, light intensity inside an optical waveguide is highest around the light emission mirror facet 20a. Since COD becomes more likely to occur as light output is increased, it is preferable to restrict, as compared with the case where the amount of injected current on the side of the light reflection mirror facet 20b is restricted, the amount of injected current on the side of the light emission mirror facet 20a where light output is higher than that through the light reflection mirror facet 20b.

The electrical resistance (film resistance) of the p-side ohmic contact 11 is an important parameter for controlling the amount of current injected into the light emission mirror facet 20a. The amount of current injected into an area far from a power supply source (the p-side pad contact 13) decreases with the resistance of the metal contact. Thus, when the provision of the p-side ohmic contact 11 having an unduly large thickness d allows the film resistance of the metal contact to be unduly reduced, it becomes difficult to improve a COD level by reducing the amount of current injected into the light emission mirror facet 20a without causing adverse effects on the other characteristics of the laser chip. Consequently, the maximum value of the thickness d of the p-side ohmic contact 11 is preferably set at 100 nm (0.1 μm) or less as described previously in consideration of the fact that it is also necessary to prevent the p-side ohmic contact 11 from hanging down on the mirror facets 20 (this causes interference) when the laser chip is fabricated or driven.

The minimum value of the thickness d of the p-side ohmic contact 11 is preferably set at 5 nm (0.005 μm) or more as described previously in consideration of conditions that, for example, the p-side ohmic contact 11 can be stably formed as a film without undergoing three-dimensional growth and does not deform at a high temperature when the laser chip is driven.

In order to prevent, for example, variations in the electrical resistivity of the metal contact and an increase in operating voltage (drive voltage) due to thermal treatment in a fabrication process and current injection when the laser chip is driven, it is more preferable to set the thickness d of the p-side ohmic contact 11 at 10 nm (0.01 μm) or more but 50 nm (0.05 μm) or less. It is much more preferable to set the thickness d of the p-side ohmic contact 11 at 10 nm (0.01 μm) or more but 25 nm (0.025 μm) or less. When the setting is made as described above, it is possible to prevent variations in the quality of the etching of the p-side ohmic contact 11 in the fabrication process, which will be described later. This makes it possible to prevent the p-side ohmic contact 11 from being poorly formed. It is also possible to prevent adherence of the p-side ohmic contact 11 and thus facilitate the fabrication of the nitride semiconductor laser chip. Consequently, fabrication yields can be improved.

A description will now be given of an experiment that was performed to determine the amount of current injected into the active layer 5 through the light emission mirror facet 20a.

In order to find variations in the amount of current injected into the light emission mirror facet 20a when the distance L1 is varied in the nitride semiconductor laser chip of the embodiment, current injection ratios (the ratio of the amount I of injected current to the amount I₀ of current injected into an area directly below the p-side pad contact 13: I/I₀) at distances in a direction from the p-side pad contact 13 to the light emission mirror facet 20a were determined by calculation.

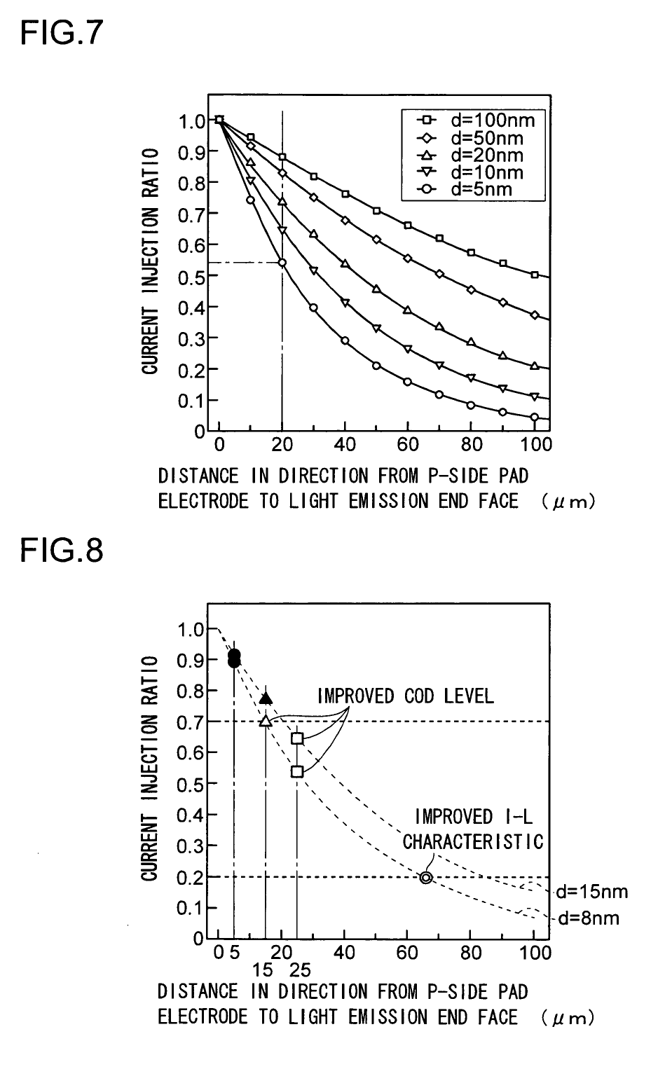

FIG. 7 is a graph showing the relationship between the distances in the direction from the p-side pad contact to the light emission mirror facet and the current injection ratios. The vertical axis of FIG. 7 shows the ratio (the current injection ratio) of the amount I of injected current at each distance to the amount I₀ of current injected into the area directly below the p-side pad contact 13; the horizontal axis of FIG. 7 shows the distance (μm) in the direction from (the mirror facet 13a of) the p-side pad contact 13 to the light emission mirror facet 20a. Since the amount I of injected current varies according to the thickness d of the p-side ohmic contact 11, the calculated values for various thicknesses are shown in FIG. 7. In FIG. 7, it is assumed that the resistivity of the p-side ohmic contact 11 is 10 μΩ·cm and that a one-dimensional model is provided in which the ridge portion 10 is regarded as a line and no current is injected from the sides of the ridge portion 10.

As will be understood from FIG. 7, for any thickness d of the p-side ohmic contact 11, the current injection ratio exponentially decreases with the distance from the p-side pad contact 13. The reduction rate of the current injection ratio decreases with the thickness d of the p-side ohmic contact 11. Thus, in order to inject a predetermined amount of current or less into the vicinity of the light emission mirror facet 20a to improve a COD level, it is necessary to increase the distance L1 from the p-side pad contact 13 to the light emission mirror facet 20a as the thickness d of the p-side pad contact 13 is increased.

In order to improve the steeply rising portion of the I-L characteristic curve of the nitride semiconductor laser chip, it is necessary to reduce the amount of light absorbed in a saturable absorption region to a given threshold or less by injecting a predetermined amount of current or more into the region in the distance L1 (into the vicinity of the light emission mirror facet 20a). It can be understood from FIG. 7 that even when the thickness d of the p-side ohmic contact 11 is set at a thickness d of 5 nm (0.005 μm), which is the smallest of thicknesses shown in FIG. 7 and the distance in the direction from the p-side pad contact 13 to the light emission mirror facet 20a is set at about 20 μm, which is practicable for the fabrication of the chip, it is possible to obtain a current injection ratio of about 0.5 (50%). Thus, it is clear that even when the thickness d of the p-side ohmic contact 11 is set at an extremely small thickness of about 5 nm and the distance L1 from the p-side pad contact 13 to the light emission mirror facet 20a is set at about 20 μm, a current of about 50% of the current injected into the active layer 5 through the area directly below the p-side pad contact 13 is injected into the active layer 5 through the light emission mirror facet 20a. Thus, it is found that the provision of the p-side ohmic contact 11 that reaches the light emission mirror facet 20a (the mirror facet 20) allows the amount of light absorbed in the saturable absorption region to be dramatically reduced as compared with the case where no current is injected into the vicinity of the light emission mirror facet 20a.

Thus, it is found that, by adjusting the thickness d of the p-side ohmic contact II and the distance L1 from the p-side pad contact 13 to the light emission mirror facet 20a, it is possible not only to improve a COD level but also to inject into the light emission mirror facet 20a a current that does not affect the rising portion of the I-L characteristic curve. When the thickness d is increased, the distance L1 can be increased. Thus, in this case, a sufficient margin for a separation region can be provided in a chip separation process, which will be described later. Thus, the fabrication process is facilitated.

In contrast, the average amount of current injected into the region in the distance L1 is reduced, and thus series resistance is increased in terms of a current-voltage (I-V) characteristic for the entire chip. Thus, when such influence on the I-V characteristic is taken into account, it is undesirable that the distance L1 is too large. When this is taken into account, the distance L1 is preferably 20% or less of the laser length L (see FIG. 2). With this configuration, it is possible not only to facilitate the fabrication process but also to reduce an increase in the drive voltage.

Based on the above findings, an experiment was performed to find the COD level and the I-L characteristic. In this experiment, for the nitride semiconductor laser chip of the embodiment, two types of nitride semiconductor laser chips were fabricated in which the thicknesses d of the p-side ohmic contacts 11 were set at 8 nm and 15 nm, and the COD level and the I-L characteristic were measured. For the measurement of the COD level, six nitride semiconductor laser chips were used in which the distances L1 from the p-side pad contacts 13 to the light emission mirror facets 20a were set at 5 μm, 15 μm and 25 μm. For the measurement of the I-L characteristic, a nitride semiconductor laser chip was fabricated in which the thickness d of the p-side ohmic contact II was set at 8 nm and the current injection ratio was reduced to 0.2 (20%) and the nitride semiconductor laser chip thus fabricated was used.

FIG. 8 is a graph showing the measurement results of the characteristics of the chips. The vertical axis of FIG. 8 shows the current injection ratio, as in FIG. 7; the horizontal axis of FIG. 8 shows the distance (μm) in the direction from (the mirror facet 13a of) the p-side pad contact 13 to the light emission mirror facet 20a, as in FIG. 7. In the chips in which the thicknesses d of the p-side ohmic contacts 11 were set at 8 nm and 15 nm, their current injection ratios at distances in the direction from the p-side pad contact 13 to the light emission mirror facet 20a were determined by calculation, as in FIG. 7, and the calculation results are indicated by broken lines shown in FIG. 8.

As will be understood from FIG. 8, the following was found. Of the chips () having a distance L1 of 5 μm, both the chips in which the thicknesses d of the p-side ohmic contacts 11 were 8 nm and 15 nm showed no improvement in COD level. Of the chips (Δ and ▴) having a distance L1 of 15 μm, the chip (Δ) in which the thickness d of the p-side ohmic contact 11 was 8 nm showed an improvement in COD level, but the chip (▴) in which the thickness d of the p-side ohmic contact 11 was 15 nm showed no improvement in COD level. Of the chips (□) having a distance L1 of 25 μm, both the chips in which the thicknesses d of the p-side ohmic contacts 11 were 8 nm and 15 nm showed an improvement in COD level. In the chip (Δ) in which the distance L1 was 15 μm and the thickness d of the p-side ohmic contact 11 was 8 nm and the chips (□) having a distance L1 of 25 μm, their COD levels were increased by a factor of 1.5 as compared with the COD level of the chip (∘) in which the distance L1 is 5 μm. Thus, it is found that in order to improve a COD level, it is necessary to set the current injection ratio of the light emission mirror facet 20a at about 0.7 (70%) or less.

In the chip in which the thickness d of the p-side ohmic contact 11 was set at 8 nm and the current injection ratio was reduced to 0.2 (20%), the I-L characteristic was measured. As a result, the I-L characteristic curve did not rise steeply even when the current injection ratio was reduced to 0.2 (20%). That is, in the chip (⊚) in which the current injection ratio was 0.2 (20%), the I-L characteristic was found to be improved. Thus, it is found that in order to improve the steeply rising portion of the I-L characteristic curve, it is necessary to set the current injection ratio of the light emission mirror facet 20a at about 0.2 (20%) or more.

Thus, it is found that in order not only to improve the COD level but also to prevent the I-L characteristic curve from rising steeply, the amount of current injected into the active layer 5 through the light emission mirror facet 20a is preferably set at 20% (0.2) or more but 70% (0.7) or less of the amount of current injected into the active layer 5 through the area directly below the p-side pad contact 13.

The relationship of formula (2) below holds between the current injection ratio and the distance in the direction from the p-side pad contact to the light emission mirror facet (the mirror facet):

$${I}_{nom} = exp ( \frac{- {L}_{A}}{\sqrt{{R}_{s} / {R}_{m}} \sqrt{d}} ) \qquad ( 2 )$$

where L_{A} represents a distance (μm) in the direction from the p-side pad contact to the light emission mirror facet (the mirror facet), Iₙₒₘ represents a current injection ratio (the ratio of the amount I of injected current to the amount I₀ of current injected into the area directly below the p-side pad contact: I/I₀) at the distance L_{A} from the p-side pad contact, Rₘ represents the resistivity of the p-side ohmic contact, d represents the thickness (μm) of the p-side ohmic contact and Rₛ represents a series resistance component of the nitride semiconductor attached to the p-side ohmic contact, per unit area.

When, in above formula (2), 0.2 or 0.7 is substituted into Iₙₒₘ, and 10 μΩ·cm and 2.04×10⁻⁴ μΩ·cm² are substituted into Rₘ and Rₛ, respectively, formula (2) gives formula (3) below:

$$161 \leq \frac{{L}_{A}}{\sqrt{d}} \leq 727 \qquad ( 3 )$$

The distance L_{A} in formula (3) corresponds to the distance L1 from the p-side pad contact 13 to the light emission mirror facet 20a, and thus the relationship of formula (1) described previously holds between the distance L1 from the p-side pad contact 13 to the light emission mirror facet 20 and the thickness d of the p-side ohmic contact 11.

A chip was fabricated so as to satisfy formula (1) described above, and the characteristics of the chip were measured. In the chip thus fabricated, the thickness d of the p-side ohmic contact 11 was set at 15 nm (0.015 μm), and the distance L1 from the p-side pad contact 13 to the light emission mirror facet 20a was set at 25 μm based on the configuration of the nitride semiconductor laser chip of the embodiment. The distance L2 from the p-side pad contact 13 to the light reflection mirror facet 20b was set at 5 μm.

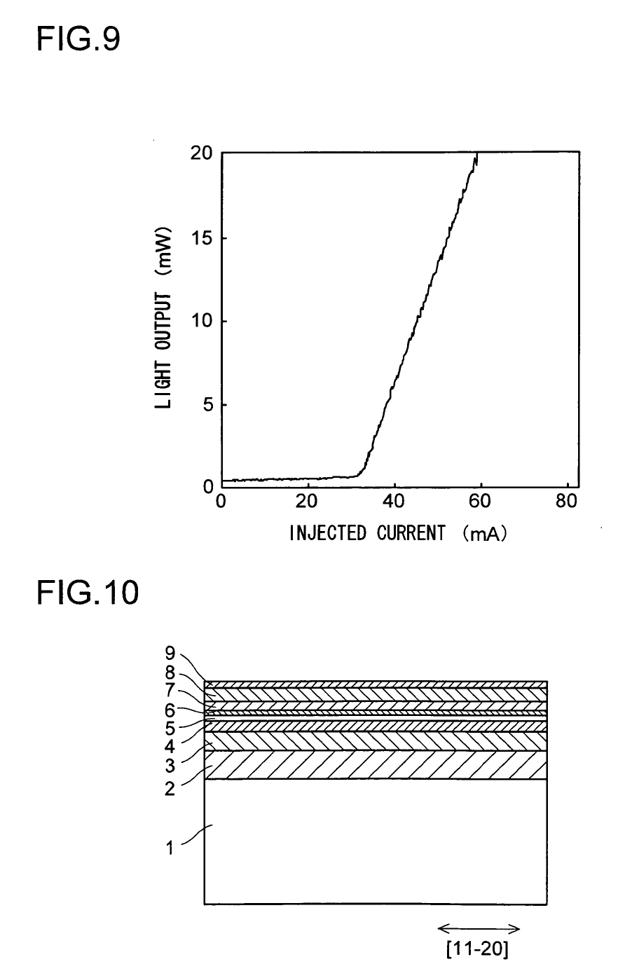

A semiconductor laser device (laser device) was assembled with the fabricated chip and was driven for a few hours, and then the characteristics of the chips were measured. Consequently, a threshold current of 35 mA and a slope efficiency of 1.2 W/A were obtained as satisfactory results. The semiconductor laser chip stably lased at a wavelength of 405 nm. It was found that, as shown in FIG. 9, the steeply rising portion of the I-L characteristic curve was improved. The COD level was measured, and consequently the COD level was obtained that was higher, by 140 mW or more, than that of a chip failing to satisfy formula (1).

In this embodiment, as described above, by setting the amount of current injected into the light emission mirror facet 20a at 20% or more of the amount of current injected into the area directly below the p-side pad contact 13, it is possible to prevent the I-L characteristic curve from disadvantageously rising steeply due to the fact that the amount of current injected into the light emission mirror facet 20a is less than 20% of the amount of current injected into the area directly below the p-side pad contact 13. That is, since light loss occurring in the saturable absorption region of the mirror facet 20 can be reduced by injecting into the light emission mirror facet 20a 20% or more of the amount of current injected into the area directly below the p-side pad contact 13, it is possible to effectively reduce the amount of light absorbed. This makes it possible to prevent the rapid occurrence of lasing. Thus, it is possible to prevent the I-L characteristic curve from rising steeply.

In this embodiment, by setting the amount of current injected into the light emission mirror facet 20a at 70% or less of the amount of current injected into the area directly below the p-side pad contact 13, it is possible to avoid the disadvantage of making it difficult to improve the COD level due to the fact that the amount of current injected into the light emission mirror facet 20a is more than 70% of the amount of current injected into the area directly below the p-side pad contact 13. As described above, with the nitride semiconductor laser chip of the embodiment, by setting the amount of current injected into the light emission mirror facet 20a at 20% or more but 70% or less of the amount of current injected into the area directly below the p-side pad contact 13, it is possible not only to improve the COD level but also to prevent the I-L characteristic curve from rising steeply.

With this configuration, since a predetermined amount of current is also injected into the vicinity of the light emission mirror facet 20a, it is possible to reduce the operating voltage as compared with a conventional nitride semiconductor laser chip having a current injection prevention region in which no current is injected into the vicinity of the light emission mirror facet 20a (the mirror facet 20).

In this embodiment, it is possible to easily set the amount of current injected into the light emission mirror facet 20a at 20% or more but 70% or less of the amount of current injected into the area directly below the p-side pad contact 13 by performing the following: the p-side ohmic contact 11 having the thickness d is formed so as to reach the light emission mirror facet 20a (the mirror facet 20); the p-side pad contact 13 is formed in a region only the distance L1 away from the light emission mirror facet 20a; and the thickness d of the p-side ohmic contact 11 and the distance L1 from the p-side pad contact 13 to the light emission mirror facet 20a are set so as to satisfy formula (1) described previously. Thus, it is easily possible not only to improve the COD level but also to prevent the I-L characteristic curve from rising steeply.

In this embodiment, both the distance L1 from the p-side pad contact 13 to the light emission mirror facet 20a and the thickness d of the p-side ohmic contact 11 are varied, and this allows the amount of current injected into the light emission mirror facet 20a to be adjusted. Thus, it is possible to keep the distance L1 from the p-side pad contact 13 to the light emission mirror facet 20a equal to or more than a predetermined distance. This makes it possible to prevent the distance L1 from the p-side pad contact 13 to the light emission mirror facet 20a from being unduly reduced. Hence, it is possible to avoid the disadvantage of, for example, making it difficult to divide (separate) the chips due to the fact that the distance L1 is unduly reduced. This makes it possible to facilitate the fabrication process, and thus the nitride semiconductor laser chip that can not only improve the COD level but also prevent the I-L characteristic curve from rising steeply can be obtained with a high yield.

In this embodiment, by setting the thickness d of the p-side ohmic contact 11 at 5 nm (0.005 μm) or more but 100 nm (0.1 μm) or less, it is possible not only to satisfactorily form the p-side ohmic contact 11 suitable for injection of a current into the vicinity of the light emission mirror facet 20a but also to reduce the amount of current injected into the vicinity of the light emission mirror facet 20a without causing adverse effects on other characteristics of the chip, such as an increased drive voltage. Thus, it is possible to improve the COD level. When the thickness d of the p-side ohmic contact 11 is set at 0.01 μm or more but 0.05 μm or less, it is possible to more satisfactorily form the p-side ohmic contact 11 suitable for not only improving the COD level but also preventing the I-L characteristic curve from rising steeply. When the thickness d of the p-side ohmic contact 11 is set at 10 nm (0.01 μm) or more but 25 nm (0.025 μm) or less, since poor formation of the p-side ohmic contact 11 or the like can be avoided, it is possible to much more satisfactorily form the p-side ohmic contact 11 suitable for not only improving the COD level but also preventing the I-L characteristic curve from rising steeply.

In this embodiment, by setting the distance L1 from the p-side pad contact 13 to the light emission mirror facet 20a at 20% or less of the laser length L, it is possible to prevent the amount of current injected into the entire chip from being unduly reduced due to the fact that the distance L1 from the p-side pad contact 13 to the light emission mirror facet 20a is larger than 20% of the laser length L. Thus, it is possible not only to facilitate the fabrication process but also to prevent the operating voltage (drive voltage) from being increased.

In this embodiment, by setting the distance L2 from the p-side pad contact 13 to the light reflection mirror facet 20b smaller than the distance L1 from the p-side pad contact 13 to the light emission mirror facet 20a, it is possible to easily prevent the amount of current injected into the entire chip from being reduced. This makes it possible to easily prevent the operating voltage (drive voltage) from being increased.

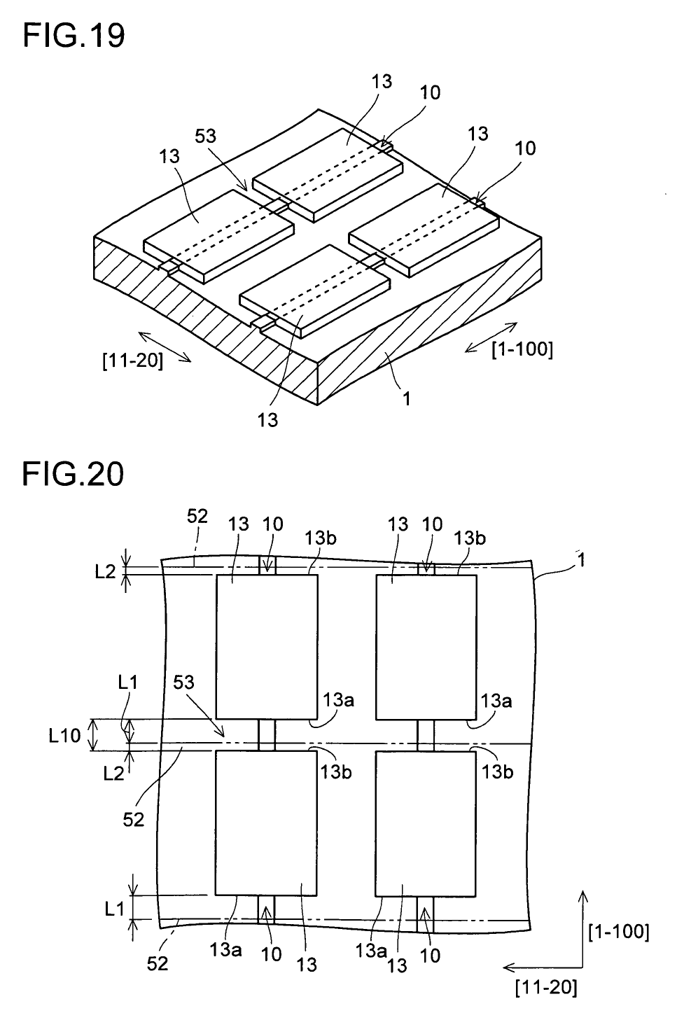

FIGS. 10 to 23 are diagrams for describing a method of fabricating the nitride semiconductor laser chip according to the embodiment of the present invention. With reference to FIGS. 1 and 5 and FIGS. 10 to 23, a description will now be given of the method of fabricating the nitride semiconductor laser chip according to the embodiment of the invention.

As shown in FIG. 10, nitride semiconductor layers 2 to 9 are first deposited on the n-type GaN substrate 1 by MOCVD (metal organic chemical vapor deposition). Specifically, the following layers are developed on the (0001) face of the n-type GaN substrate 1 one after another: the lower contact layer 2 having a thickness of about 0.1 μm to about 10 μm (for example, about 4 μm) and formed of n-type GaN; the lower cladding layer 3 having a thickness of about 0.5 μm to about 3.0 μm (for example, about 2 μm) and formed of n-type Al_{0.05}Ga_{0.95}N; the lower guiding layer 4 having a thickness of 0 to about 0.2 μm (for example, about 0.1 μm) and formed of n-type GaN; and the active layer 5. When the active layer 5 is developed, as shown in FIG. 5, the four barrier layers 5b having a thickness of about 8 nm and formed of Inₓ₂Ga₁₋ₓ₂N (x2=0 to 0.05) and the three quantum well layers 5a having a thickness of about 4 nm and formed of Inₓ₁Ga₁₋ₓ₁N (x1=0.05 to 0.1) are alternately developed. Thus, on the lower guiding layer 4, the active layer 5 is formed that has a MQW structure composed of the three quantum well layers 5a and the four barrier layers 5b.

Then, as shown in FIG. 10, the following layers are developed on the active layer 5 one after another: the evaporation prevention layer 6 having a thickness of 0 to about 0.02 μm (for example, about 0.01 μm) and formed of p-type Al_{0.3}Ga_{0.7}N; the upper guiding layer 7 having a thickness of 0 to about 0.2 μm (for example, about 0.01 μm) and formed of p-type GaN; the upper cladding layer 8 having a thickness of about 0.1 μm to about 1.0 μm (for example, about 0.5 μm) and formed of p-type Al_{0.05}Ga_{0.95}N; and the upper contact layer 9 having a thickness of about 0.01 μm to about 1.0 μm (for example, about 0.05 μm) and formed of p-type GaN.

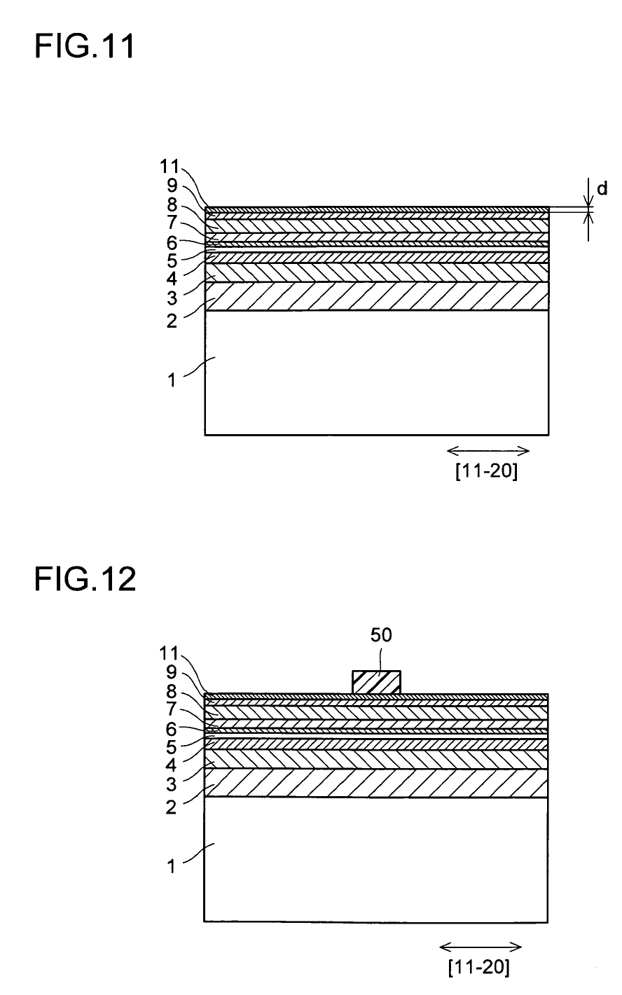

Then, as shown in FIG. 11, the p-side ohmic contact 11 of Pd is formed on the upper contact layer 9 by vacuum evaporation or the like. Here, the p-side ohmic contact 11 is formed such that its thickness is 5 nm (0.005 μm) or more but 100 nm (0.1 μm) or less (for example, 15 nm). Then, as shown in FIG. 12, on the p-side ohmic contact 11, a resist 50 is formed by photolithography such that it has a width of about 1 μm to about 3 μm (for example, about 1.5 μm), extends in the [1-100] direction and is stripe-shaped (elongated).

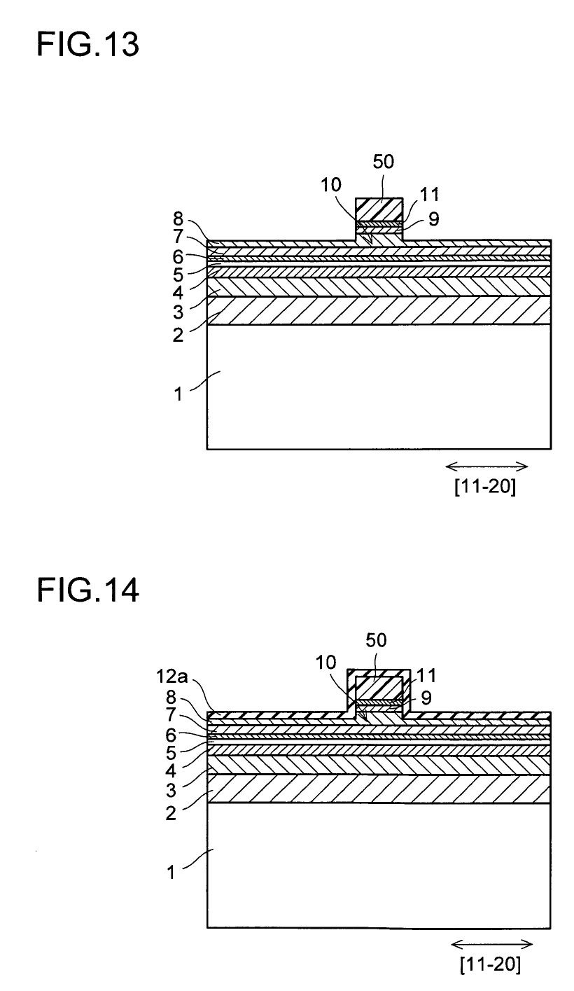

Then, as shown in FIG. 13, the upper cladding layer 8 is etched halfway through its depth, using the resist 50 as a mask, by RIE (reactive ion etching) in which a gas such as a chlorine-based gas like SiCl₄ or Cl₂ or an Ar gas is used. In this way, the ridge portion 10 is formed that is composed of the projection portion of the upper cladding layer 8 and the upper contact layer 9, extends in the [1-100] direction and is stripe-shaped (elongated).

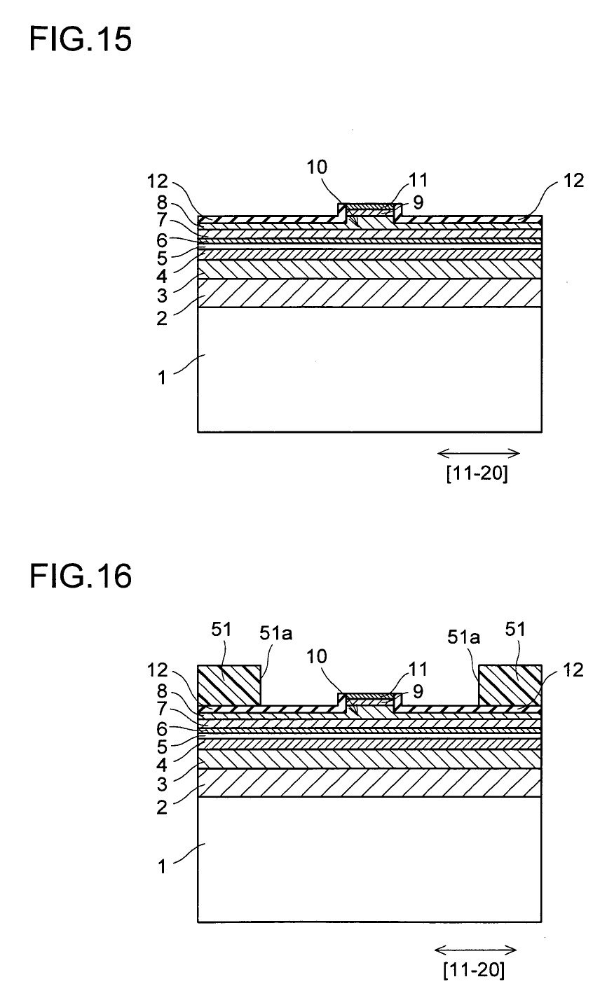

Then, as shown in FIG. 14, with the resist 50 left on the ridge portion 10, the buries layer 12a having a thickness of about 0.1 μm to about 0.3 μm (for example, about 0.15 μm) and formed of SiO₂ is formed by sputtering or the like, and the ridge portion 10 is buried. Then, the resist 50 is removed by liftoff, and thus the p-side ohmic contact 11 in the upper portion of the ridge portion 10 is exposed. By doing so, the buried layers 12 shown in FIG. 15 are formed on both sides of the ridge portion 10.

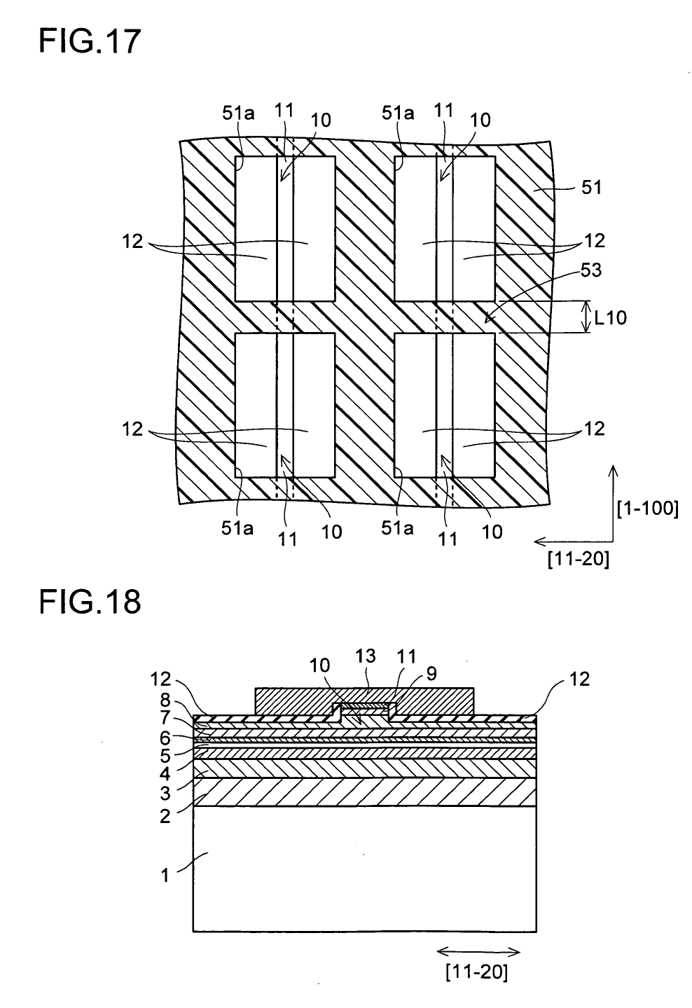

Then, as shown in FIGS. 16 and 17, the resist 51 is formed on the entire upper surface of the substrate (wafer) on which the buried layers 12 are formed, and a plurality of openings 51a through which predetermined regions including parts of the ridge portions 10 (the p-side ohmic contacts 11) are exposed are formed by photolithography. Here, as shown in FIG. 17, the openings 51a are formed such that they are substantially rectangular as seen in a plan view and that they are arranged, with the openings 51a spaced the distance L10 (for example, 30 μm) apart, in the direction (the [1-100] direction) in which the ridge portion 10 extends.

Regions (regions in the distances L10) between the adjacent openings 51a among a plurality of openings 51a formed on the ridge portion 10 serve as the separation regions 53 that are used for separation of the chips in a later process. Thus, the distances L10 between the adjacent openings 51a are adjusted such that the p-side pad contacts 13 formed within the openings 51a are separated to have a width satisfying at least formula (1) described previously. Here, with respect to the width L10 of the separation region 53, since the separation region 53 is separated later into the light emission mirror facet 20a and light reflection mirror facet 20b by cleavage or the like, the width L10 is preferably set with consideration given to variations in the width L10 caused by the separation. The pattern distance of the opening 51a in the direction (the [1-100] direction) in which the ridge portion 10 extends is set equal to the laser length L of a required nitride semiconductor laser chip.

Then, on the substrate (wafer) on which the resist 51 is formed, the Ti layer (unillustrated), the Mo layer (unillustrated) and the Au layer (unillustrated) are deposited one after another from the side of the substrate (wafer) by vacuum evaporation or the like, with the result that the p-side pad contact having a multilayer structure is formed. Thereafter, the resist 51 is removed by liftoff, and thus the p-side pad contact is patterned. In this way, as shown in FIGS. 18 to 20, in the regions on the buries layers 12 corresponding to the openings 51a of the resist 51, a plurality of p-side pad contacts that are substantially rectangular as seen in a plan view are formed in a matrix. As shown in FIG. 18, the p-side pad contact 13 is formed so as to cover part of the p-side ohmic contact 11 (so as to come into direct contact with part of the upper surface of the p-side ohmic contact 11), and, as shown in FIG. 20, the p-side pad contacts 13 are spaced the distance L10 (for example, 30 μm) apart in the direction (the [1-100] direction) in which the ridge portion 10 extends.

Then, in order to facilitate the division of the substrate (wafer), cutting and grinding are performed on the back of the n-type GaN substrate 1, and thus the thickness of the n-type GaN substrate 1 is reduced to about 80 μm to about 150 μm (for example, about 130 μm). Then, the surface on which the cutting and grinding have been performed is adjusted by dry etching or the like.

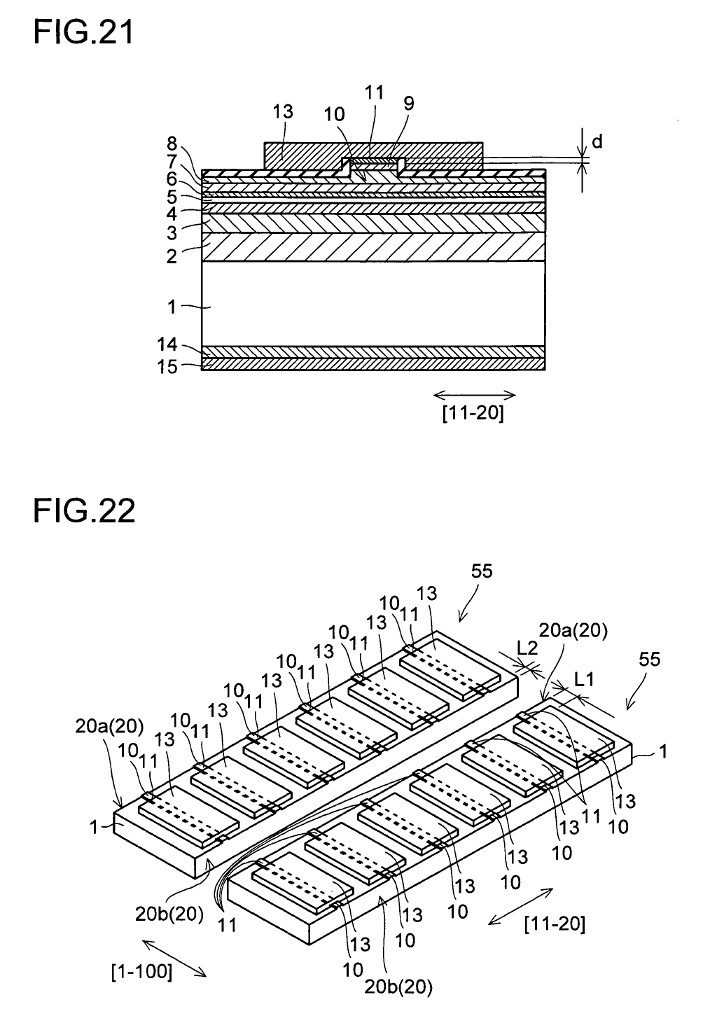

Then, as shown in FIG. 21, on the back of the n-type GaN substrate 1, the Hf layer (unillustrated) and the Al layer (unillustrated) are deposited, by vacuum evaporation or the like, one after another from the back side of the n-type GaN substrate 1, and thus the n-side metal contact 14 having a multilayer structure is formed. Then, on the n-side metal contact 14, the Mo layer (unillustrated), the Pt layer (unillustrated) and the Au layer (unillustrated) are deposited one after another from the side of the n-side metal contact 14, and thus the n-side pad contact 15 having a multilayer structure is formed. The n-side pad contact 15 is formed so as to cover the n-side metal contact 14. In order to, for example, adjust electrical properties on the negative side, before the n-side metal contact 14 is formed, dry etching or wet etching may be performed.

Then, as shown in FIG. 22, the substrate (wafer) is separated by cleavage, and thus the mirror facets 20 are formed. The substrate (wafer) is cleaved, such as by scribing and braking or laser scribing, along separation lines 52 in the separation region 53 shown in FIG. 20. In this way, the substrate (wafer) is separated along the separation lines 52, and the mirror facets 20 are formed along the [11-20] direction. By the separation of the substrate (wafer), a mirror facet 20 serving as the light emission mirror facet 20a of one of the adjacent chips and a mirror facet 20 serving as the light reflection mirror facet 20b of the other adjacent chip are formed simultaneously. With the above-described process for chip separation, chips 55 arranged in the shape of a bar are obtained.

In this embodiment, the distance L10 between the p-side pad contacts 13 is distributed by the separation line 52 such that a distance from the separation line 52 (see FIG. 20) to one of the p-side pad contacts 13 is the distance L1 (for example, 25 μm) and a distance from the separation line 52 to the other p-side pad contact 13 is the distance L2 (for example, 5 μm); the substrate (wafer) is cleaved along the separation lines 52. That is, the substrate (wafer) is separated such that the distance from the mirror facet 20 to one of the p-side pad contacts 13 is L1 (25 μm) and the distance from the mirror facet 20 to the other adjacent p-side pad contact 13 is L2 (5 μm). Since the chips separated from the substrate (wafer) are designed such that their laser lengths L are equal to each other, the width between the p-side pad contacts 13 is distributed between the side of the light emission mirror facet 20a and the side of the light reflection mirror facet 20b in a uniform proportion in any of the chips.

Thus, with the above-described process, it is possible to determine the distance L1 from the mirror facet 20 to one of the p-side pad contacts 13 (the mirror facet 13a). In this case, by shifting the position of the separation line 52 from the center position of the width L10 to the side of the other p-side pad contact 13 (the mirror facet 13b) (by distributing the length L10 asymmetrically), it is possible to decrease the length L2 from the other p-side pad contact 13 to the mirror facet 20 (the light reflection mirror facet 20b) as compared with the length L1 from the one of the p-side pad contacts 13 to the mirror facet 20 (the light emission mirror facet 20a), as described above.

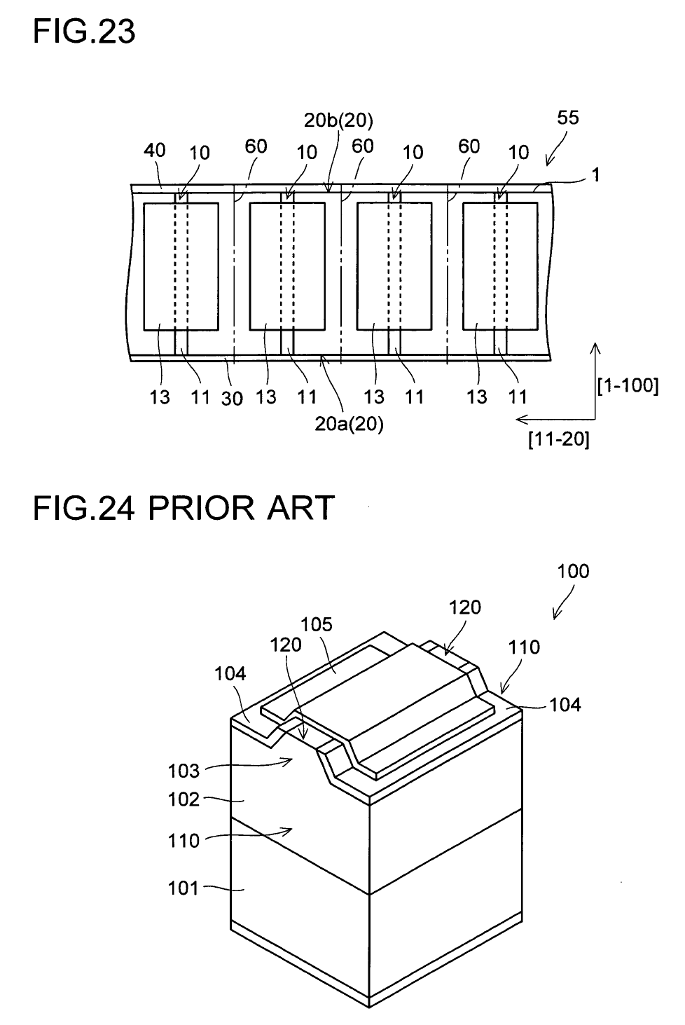

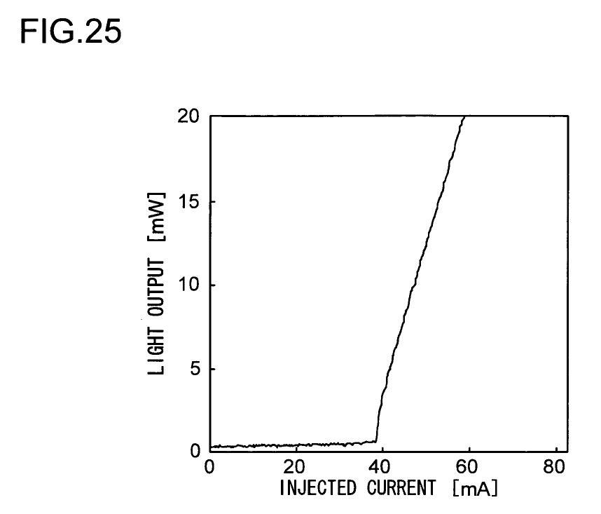

Thereafter, as shown in FIG. 23, coatings are applied, by vapor deposition, sputtering or the like, to the mirror facets (the mirror facets 20) of the chips 55 arranged in the shape of a bar. Specifically, on the light emission mirror facet 20a is formed the AR (anti-reflection) coating layer 30 composed of two layers in which the aluminum nitride layer (unillustrated) and the aluminum oxide layer (unillustrated), for example, are deposited from the side of the light emission mirror facet 20a. On the light reflection mirror facet 20b is formed the HR (high-reflection) coating layer 40 in which the silicon oxide layers (unillustrated) and the titanium oxide layers (unillustrated), for example, are alternately deposited such that a total of nine layers are deposited.

Finally, the chips 55 arranged in the shape of a bar are separated, along separation lines 60 extending in the [1-100] direction, into individual chips. In this way, the nitride semiconductor laser chip shown in FIG. 1 and according to the embodiment of the present invention is fabricated.

As described above, with the method of fabricating the nitride semiconductor laser chip according to this embodiment, by forming a plurality of p-side pad contacts 13 in the direction (the [1-100] direction) in which the ridge portion 10 extends such that they are spaced the distance L10 apart and cleaving the substrate (wafer) such that the distance L1 from the position (the position of the separation line 52) where the mirror facet 20 is formed to one of the adjacent p-side pad contacts 13 is different from the distance L2 from the position where the mirror facet 20 is formed to the other adjacent p-side pad contact 13, it is possible to simultaneously form the light emission mirror facet 20a of one of the adjacent chips (laser chips) and the light reflection mirror facet 20b of the other adjacent chip (laser chip) and to easily adjust the distance L1 from the light emission mirror facet 20a to the one of the adjacent p-side pad contacts 13 and the distance L2 from the light reflection mirror facet 20b to the other adjacent p-side pad contact 13 such that the distance L1 is larger than the distance L2.

Thus, it is possible to easily adjust the amount of current injected into the light emission mirror facet 20a to a predetermined amount (20% or more but 70% or less) that is smaller than the amount of current injected into the area directly below the p-side pad contact 13. This makes it possible to easily fabricate the nitride semiconductor laser chip that can not only improve a COD level but also prevent an I-L characteristic curve from rising steeply. Consequently, the nitride semiconductor laser chip can be fabricated with a high yield.

In this embodiment, by adjusting the distance L10 between one of the adjacent p-side pad contacts 13 and the other adjacent p-side pad contact 13 in the direction (the [1-100] direction) in which the ridge portion 10 extends to a predetermined distance that makes it easy to perform cleavage, it is possible to easily separate the chips.

In this embodiment, the distance L2 from the p-side pad contact 13 to the light reflection mirror facet 20b can be easily set smaller than the distance L1 from the p-side pad contact 13 to the light emission mirror facet 20a. Thus, it is possible to easily fabricate the nitride semiconductor laser chip in which the operating voltage (drive voltage) is prevented from being increased (in which the operating voltage can be reduced).

The presently disclosed embodiment should be considered in all respects as illustrative and not restrictive. The scope of the present invention is indicated not by the above description of the embodiment but by the scope of the claims, and the invention includes the meaning equivalent to the scope of the claims and all modifications within the scope of the claims.

For example, although the above embodiment deals with the case where the n-type GaN substrate is used as the substrate, the present invention is not limited to this case. A substrate formed of a material such as InGaN, AlGaN or AlGaInN or an insulted substrate such as a sapphire substrate may be used. In the nitride semiconductor layers formed on the substrate by crystal growth, combinations or modifications may be possible, as appropriate, on thickness, composition and the like such that their desired characteristics are achieved. For example, semiconductor layers may be added or deleted or the order in which the semiconductor layers are deposited may be partly changed. In some of the semiconductor layers, their conductivity types may be changed. That is, any other modifications may be freely made as long as the basic characteristics of the nitride semiconductor laser chip are achieved.

Although the above embodiment deals with the case where the buried layers are formed of SiO₂, the invention is not limited to this case. The buried layers may be formed of any insulating material other than SiO₂. For example, the buried layers may be formed of SiN, Al₂O₃ or ZrO₂.

Although the above embodiment deals with the case where the p-side ohmic contact is formed of Pd, the invention is not limited to this case. The p-side ohmic contact may be formed of any material other than Pd as long as such a material has a large work function. For example, the p-side ohmic contact may be formed of a material such as Ni, Pt or Au.

Although the above embodiment deals with the case where the p-side pad contact is about 0.2 μm thick, the invention is not limited to this case. The thickness of the p-side pad contact may be more than 0.2 μm. The p-side pad contact may be formed with a thick film having a thickness on the order of micrometers.

Although the above embodiment deals with the case where the p-side pad contact is formed by depositing the Ti layer, the Mo layer and the Au layer one after another from the side of the buried layers, the invention is not limited to this case. The p-side pad contact may be formed by depositing the Mo layer and the Au layer one after another from the side of the buried layers.

Although the above embodiment deals with the case where the n-type metal contact is formed by depositing the Hf layer and the Al layer one after another from the back of the n-type GaN substrate, the invention is not limited to this case. The n-type metal contact may be formed by depositing, for example, the Ti layer and the Al layer one after another from the back of the n-type GaN substrate

Although the above embodiment deals with the case where the resist is used as the mask layer for the formation of the ridge portion, the invention is not limited to this case. The ridge portion can be formed with a mask layer of, for example, SiO₂. In this case, the tip (top) of the ridge portion can be exposed such as by the method in which a photolithography process and dissolution by a hydrofluoric acid solution are combined.

In the above embodiment, the p-side ohmic contact may be formed after the formation of the ridge portion. In this case, after the formation of the ridge portion and the buried layers, the patterned p-side ohmic contact is preferably formed so as to come into contact with the top of the ridge portion.

Although the above embodiment deals with the case where the mirror facets are formed by cleavage, the invention is not limited to this case. The mirror facets (the light emission mirror facet and light reflection mirror facet) may be formed by any method other than cleavage. For example, the mirror facets may be formed by dry etching or the like.

Although the above embodiment deals with the case where the invention is applied to the ridge laser structure, the invention is not limited to this case. The invention can be applied to laser structures other than the ridge laser structure, such as a BH (buried heterostructure) and a RIS (ridge by selective re-growth) structure.

Although the above embodiment deals with the case where the ridge portion is so formed as to extend in the [1-100] direction and the mirror facets are so formed as to extend in the [11-20] direction, the invention is not limited to this case. Preferably, those directions in which the ridge portion and the mirror facets extend are crystallographically equivalent to these directions. That is, the ridge portion may be so formed as to extend in a direction represented by <1-100>, and the mirror facets may be so formed as to extend in a direction represented by <11-20>.

Although the above embodiment deals with the case where the crystals of the nitride semiconductor layers are grown by MOCVD, the invention is not limited to this case. The crystals of the nitride semiconductor layers may be grown by any method other than MOCVD. The methods other than MOCVD include HVPE (hydride vapor phase epitaxy) and gas source MBE (molecular beam epitaxy).

Other than nitride semiconductor laser chips for use as light sources for optical pickups, the present invention can be applied to, for example, broad area semiconductor laser chips for use in illumination, chips, such as laser chips for use in communication, which are required to produce a high optical output and in which importance is placed on how a I-L characteristic curve rises and chips in which importance is placed on their operating voltages.

What is claimed is:

1. A nitride semiconductor laser chip comprising:
a nitride semiconductor layer formed on a substrate;
a pair of mirror facets that is formed on the nitride semiconductor layer and that includes a light emission mirror facet;
a first metal contact layer formed on the nitride semiconductor layer; and
a second metal contact layer formed, in a predetermined region on the nitride semiconductor layer and at a predetermined distance away from the light emission mirror facet, such that the second metal contact layer covers part of the first metal contact layer;
wherein an amount of current injected into the light emission mirror facet is 20% or more but 70% or less of an amount of current injected into an area directly below the second metal contact layer.

2. The nitride semiconductor laser chip of claim 1,
wherein the first metal contact layer is formed to have a thickness d and reach the light emission mirror facet, the second metal contact layer is formed in a region only a distance L1 away from the light emission mirror facet and the thickness d of the first metal contact layer and the distance L1 from the second metal contact layer to the light emission mirror facet are adjusted such that the amount of current injected into the light emission mirror facet is 20% or more but 70% or less of the amount of current injected into the area directly below the second metal contact layer.

3. A nitride semiconductor laser chip comprising:
a nitride semiconductor layer formed on a substrate;
a pair of mirror facets that is formed on the nitride semiconductor layer and that includes a light emission mirror facet;
a first metal contact layer formed on the nitride semiconductor layer; and
a second metal contact layer formed, in a predetermined region on the nitride semiconductor layer and at a predetermined distance away from the light emission mirror facet, such that the second metal contact layer covers part of the first metal contact layer;
wherein the first metal contact layer is formed to have a thickness d and reach the light emission mirror facet, the second metal contact layer is formed in a region only a distance L1 away from the light emission mirror facet and a relationship between the thickness d of the first metal contact layer and the distance L1 from the second metal contact layer to the light emission mirror facet is given by formula below:
$$161 \leq \frac{L 1}{\sqrt{d}} \leq 727.$$

4. The nitride semiconductor laser chip of claim 1,
wherein the nitride semiconductor layer includes an n-type semiconductor layer, an active layer and a p-type semiconductor layer formed one after another on the substrate from the substrate and further includes a current path that is formed on at least one of layers constituting the nitride semiconductor layer and that extends perpendicular to the mirror facets, the first metal contact layer is so formed on the current path as to come into contact with the p-type semiconductor layer and the second metal contact layer is so formed on the p-type semiconductor layer as to come into contact with part of the first metal contact layer

5. The nitride semiconductor laser chip of claim 3,
wherein the nitride semiconductor layer includes an n-type semiconductor layer, an active layer and a p-type semiconductor layer formed one after another on the substrate from the substrate and further includes a current path that is formed on at least one of layers constituting the nitride semiconductor layer and that extends perpendicular to the mirror facets, the first metal contact layer is so formed on the current path as to come into contact with the p-type semiconductor layer and the second metal contact layer is so formed on the p-type semiconductor layer as to come into contact with part of the first metal contact layer

6. The nitride semiconductor laser chip of claim 1,
wherein a thickness d of the first metal contact layer is 0.005 μm or more but 0.1 μm or less.

7. The nitride semiconductor laser chip of claim 3,
wherein the thickness d of the first metal contact layer is 0.005 μm or more but 0.1 μm or less.

8. The nitride semiconductor laser chip of claim 6,
wherein the thickness d of the first metal contact layer is 0.01 μm or more but 0.05 μm or less.

9. The nitride semiconductor laser chip of claim 7,
wherein the thickness d of the first metal contact layer is 0.01 μm or more but 0.05 μm or less.

10. The nitride semiconductor laser chip of claim 6,
wherein the thickness d of the first metal contact layer is 0.01 μm or more but 0.025 μm or less.

11. The nitride semiconductor laser chip of claim 7,
wherein the thickness d of the first metal contact layer is 0.01 μm or more but 0.025 μm or less.

12. The nitride semiconductor laser chip of claim 1,
wherein a thickness of the second metal contact layer is larger than a thickness of the first metal contact layer.

13. The nitride semiconductor laser chip of claim 3,
wherein a thickness of the second metal contact layer is larger than the thickness of the first metal contact layer.

14. The nitride semiconductor laser chip of claim 2,
wherein the distance L1 from the second metal contact layer to the light emission mirror facet is 20% or less of a distance between the mirror facets.

15. The nitride semiconductor laser chip of claim 3,
wherein the distance L1 from the second metal contact layer to the light emission mirror facet is 20% or less of a distance between the mirror facets.

16. The nitride semiconductor laser chip of claim 2,
wherein the pair of mirror facets includes a light reflection mirror facet opposite the light emission mirror facet, the first metal contact layer is formed to reach the light emission mirror facet and a distance from the light reflection mirror facet to the second metal contact layer is smaller than the distance L1 from the light emission mirror facet to the second metal contact layer.

17. The nitride semiconductor laser chip of claim 3,
wherein the pair of mirror facets includes a light reflection mirror facet opposite the light emission mirror facet, the first metal contact layer is formed to reach the light emission mirror facet and a distance from the light reflection mirror facet to the second metal contact layer is smaller than the distance L1 from the light emission mirror facet to the second metal contact layer.

18. The nitride semiconductor laser chip of claim 1,
wherein the pair of mirror facets is each formed by cleavage.

19. The nitride semiconductor laser chip of claim 3,
wherein the pair of mirror facets is each formed by cleavage.

20. A method of fabricating a nitride semiconductor laser chip, comprising the steps of:
growing an n-type semiconductor layer, an active layer and a p-type semiconductor layer one after another on a substrate, the layers being a nitride semiconductor layer;
forming, on at least one of layers constituting the nitride semiconductor layer, a current path extending in a predetermined direction;
forming, on the current path, a first metal contact layer coming into contact with the p-type semiconductor layer;
forming a second metal contact layer on the p-type semiconductor layer such that the second metal contact layer covers part of the first metal contact layer; and
forming a mirror facet by cleaving the substrate in a direction perpendicular to a direction in which the current path extends,
wherein the step of forming the second metal contact layer includes a step of forming a plurality of second metal contact layers spaced a predetermined distance apart in the direction in which the current path extends and the step of forming the mirror facet includes a step of cleaving the substrate such that, as seen in a plan view, a distance from a position where the mirror facet is formed to one of the adjacent second metal contact layers is different from a distance from the position where the mirror facet is formed to the other adjacent second metal contact layer.
